(19) United States
(12) Patent Application Publication
(10) Pub. No.: US 2024/0260435 A1
(43) Pub. Date: Aug. 1, 2024

(54) DISPLAY APPARATUS AND METHOD FOR MANUFACTURING THE SAME

(71) Applicant: LG Display Co., Ltd., Seoul (KR)

(72) Inventor: Soo Hyun PARK, Paju-si (KR)

(73) Assignee: LG Display Co., Ltd., Seoul (KR)

(21) Appl. No.: 18/420,341

(22) Filed: Jan. 23, 2024

(30) Foreign Application Priority Data
Jan. 30, 2023 (KR) 10-2023-0011917

(51) Int. Cl. H10K 59/80; H10K 71/00; H10K 102/00

(52) U.S. Cl. CPC H10K 59/8794; H10K 59/872; H10K 71/00; H10K 2102/311

(57) ABSTRACT

A display apparatus and a method of manufacturing the same are discussed. In one example, the display apparatus includes a flexible display panel having a curved portion, a cover member attached to a display surface of the display panel, and a flexible plate adhered to a rear surface of the display panel. Further, the flexible plate includes a flexible thin sheet and at least one plate.

### CROSS-REFERENCE TO RELATED APPLICATIONS

This application claims priority to Korean Patent Application No. 10-2023-0011917, filed on Jan. 30, 2023, the entire contents of which are hereby expressly incorporated by reference into the present application.

### BACKGROUND OF THE DISCLOSURE

### Technical Field

The present disclosure relates to a display apparatus and a method of manufacturing the same. Particularly, the present disclosure related to a display apparatus with improved heat dissipation and attachment configuration and to a method of manufacturing the display apparatus.

### Discussion of the Related Art

Display devices are widely used in various fields of technology and can be considered an integral part of our lives in enhancing communication among people with diverse backgrounds. As such, display devices can be considered as one of the important electronic devices in the world.

With this approach to a full-scale information age, such displays that are capable of visually expressing electrical information signals have been rapidly developed. As such, various display apparatuses having excellent performance and properties, such as slimness, light weight, and low power consumption, have been developed and used.

Among the various display apparatuses, there are a liquid crystal display (LCD) apparatus, an organic light-emitting display (OLED) apparatus, and an inorganic light-emitting display apparatus as examples of the display apparatuses. The organic light-emitting display apparatus, which can be considered a next-generation display apparatus having self-emissive properties, exhibits excellent characteristics in terms of viewing angle, contrast, response time, power consumption, etc., and is used widely in various fields and applications.

### SUMMARY OF THE DISCLOSURE

Accordingly, the present disclosure is directed to a display apparatus and a method of manufacturing the same that substantially obviate one or more problems due to limitations and disadvantages of the related art.

It is an object of the present disclosure to provide a display apparatus capable of solving or addressing heat dissipation and support limitations, by applying a flexible plate structure to a display panel having an extreme curvature, and to provide a method of manufacturing such display apparatus.

It is another object of the present disclosure to provide a display apparatus with an improved heat dissipation and attachment configuration and a method of manufacturing the display apparatus.

Objects of the present disclosure devised to solve or address the problems and challenges are not limited to the aforementioned objects, and other unmentioned objects will be clearly understood by those skilled in the art based on the following detailed description of the present disclosure.

To achieve the above objects and other advantages and in accordance with the purpose of the invention, as embodied and broadly described herein, a display apparatus includes a flexible display panel having a curved portion, a cover member attached to a display surface of the display panel, and a flexible plate adhered to a rear surface of the display panel.

According to an aspect of the present disclosure, the flexible plate can include a flexible thin sheet made of a material having a heat dissipating effect and a plate having a heat dissipating effect.

According to an aspect of the present disclosure, the plate can be disposed at a position corresponding to a flat surface or a gentle curvature portion of the display panel, excluding the curved portion.

According to an aspect of the present disclosure, the flexible thin sheet can be adhered to the rear surface of the display panel including the curved portion.

In another aspect of the present disclosure, a method of manufacturing a display apparatus includes preparing a flexible plate having a plate adhered to a flexible thin sheet, and adhering the flexible plate to a rear surface of a display panel having a curved portion.

It is to be understood that both the foregoing general description and the following detailed description of the present disclosure are examples and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1 is a block diagram schematically showing the construction of a display apparatus according to an embodiment of the present disclosure;

FIG. 2 is a sectional view of a display apparatus according to an embodiment of the present disclosure;

FIG. 3 is a more detailed sectional view of the display apparatus of FIG. 2; and

FIG. 4 is view illustrating a method of manufacturing a display apparatus according to an embodiment of the present disclosure.

### DETAILED DESCRIPTION OF THE EMBODIMENTS

Advantages and features of the present disclosure and methods of achieving the same will be more clearly understood from embodiments described below with reference to the accompanying drawings. However, the present disclosure is not limited to the following embodiments and can be implemented in various different forms. The embodiments are provided merely to complete the present disclosure and to fully inform a person having ordinary skill in the art to which the present disclosure pertains of the category of the invention.

In the drawings for explaining various embodiments of the present disclosure, for example, the illustrated shape, size, ratio, angle, and number are given by way of example, and thus, are not limitative of the present disclosure. Throughout the specification, the same reference numerals designate substantially the same constituent elements. Further, in the following description of the present disclosure, a detailed description of relevant known technology will be omitted when it may make the subject matter of the present disclosure rather unclear.

When the terms “comprises”, “includes” “has”, etc., are used in this specification, other parts can be added unless the term “only” is used. When constituent elements are expressed in singular, they can be interpreted as plural unless explicitly stated otherwise.

In the interpretation of constituent elements, the constituent elements are interpreted as including an error range even if there is no explicit description thereof.

When describing positional relationships, for example, when the positional relationship between two constituent elements is described using “on”, “above”, “over”, “below”, “aside”, or the like, one or more other constituent elements can be interposed between the constituent elements unless the term “immediately” or “directly” is used therewith.

Further, “first”, “second”, etc. can be used to distinguish between constituent elements, but the constituent elements are not limited in function or structure by the ordinal numbers in front thereof or the names thereof. These terms do not define order or sequence. Since the claims are described based on essential constituent elements, the ordinal numbers in front of the names of the constituent elements in the claims may not match the ordinal numbers in front of the names of the constituent elements in the embodiments.

The following embodiments can be partially or wholly coupled to and combined with each other, and various linkages and operations are technically possible. The embodiments can be implemented independently of each other, or can be implemented in association with each other.

Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference, unless otherwise specified.

The word “exemplary” is used to mean serving as an example or illustration, unless otherwise specified. Embodiments are example embodiments. Aspects are example aspects. Any implementation described herein as an “example” is not necessarily to be construed as preferred or advantageous over other implementations.

In the present disclosure, a ‘display apparatus’ (or ‘display device’) can include a display apparatus which includes a display panel and one or more drivers for driving the display panel, in a narrow sense, such as a liquid crystal module (LCM), an organic light emitting module (OLED module), and a quantum dot (QD) module. Further, the ‘display apparatus’ (or ‘display device’) can further include a set electronic apparatus or a set apparatus (or a set device) which is a complete product or a final product including an LCM, an OLED module, and a QD module, such as a laptop computer, a television, or a computer monitor, an automotive display apparatus or equipment display apparatus including another type of vehicle and a mobile electronic device including a smart phone or an electronic pad.

Hereinafter, a display apparatus according to the present disclosure will be described in more detail with reference to the accompanying drawings. All the components of each display apparatus or device according to all embodiments of the present disclosure are operatively coupled and configured.

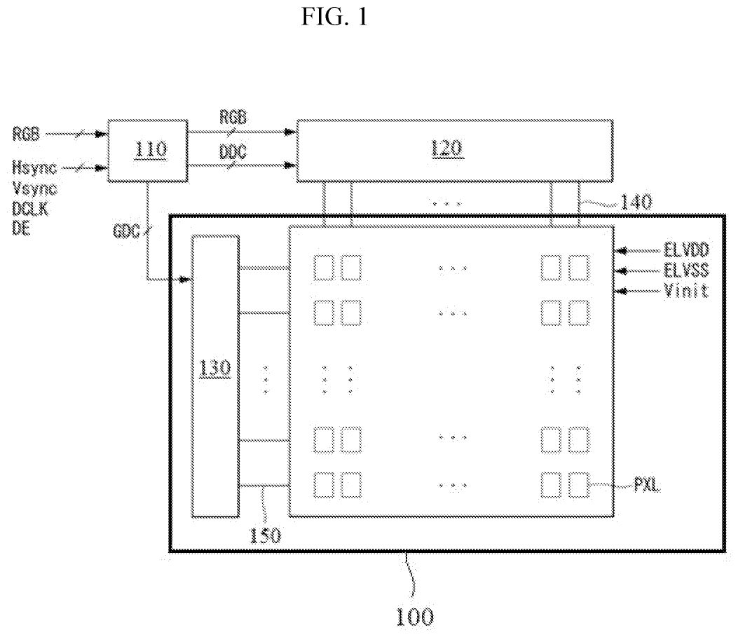

FIG. 1 is a block diagram schematically showing the construction of a display apparatus according to an embodiment of the present disclosure.

Referring to FIG. 1, the display apparatus according to the embodiment of the present disclosure includes a display panel 100 having pixels PXL formed thereon, a data drive circuit (or data driver) 120 configured to drive data lines 140, a gate drive circuit (or gate driver) 130 configured to drive gate lines 150, and a timing controller 110 configured to control operation and driving timing of the data drive circuit 120 and the gate drive circuit 130. The display panel 100 can include the gate drive circuit 130, but other variations are possible. Embodiments of the present disclosure are not limited thereto.

As the display panel 100 (or 20 in other figures) used in the embodiments of the present disclosure, any type of display panels such as a liquid crystal display panel, an organic light emitting diode (OLED) display panel, a quantum dot (QD) display panel, an electroluminescent display panel, etc. can be used.

The plurality of data lines 140 and the plurality of gate lines 150 intersect each other on the display panel 100, and the pixels PXL are disposed at intersection regions in a matrix form. However, the pixels PXL can be arranged in a non-matrix form, e.g., in clusters, etc.

In an example, pixels PXL disposed on the same horizontal line form one pixel row. Further, pixels PXL disposed in one pixel row are connected to one gate line 150, which can include at least one scan line and at least one emission line, and such rows of pixels PXL can be arranged to each other vertically so as to form a matrix configuration.

In an example, each pixel PXL can be connected to one data line 140, at least one scan line, and at least one emission line. The pixels PXL can commonly receive high-potential and low-potential drive voltages ELVDD and ELVSS and an initialization voltage Vinit from a power generator. In order to prevent unnecessary emission of an OLED (organic light emitting diode) or a light emitting element of each pixel during an initialization period and a sampling period, the initialization voltage Vinit is preferably selected within a voltage range sufficiently lower than the operating voltage of the OLED, and can be set so as to be equal to or lower than the low-potential drive voltage ELVSS.

Each of one or more thin film transistors (TFTs) constituting each of the pixels PXL can be implemented as an oxide TFT including, for example, an oxide semiconductor layer. The oxide TFT is advantageous to an increase in area of the display panel 100 when electron mobility, process variation, etc., are considered. The present disclosure is not limited thereto, and the semiconductor layer of the TFT can be made of amorphous silicon or polysilicon.

Each pixel PXL can include a light-emitting element, a drive TFT configured to supply current to the light-emitting element, a switching TFT configured to supply a data voltage to the drive TFT, and a storage capacitor configured to maintain the data voltage supplied to the drive TFT for one frame. The light-emitting element of each pixel PXL can be an organic light emitting diode (OLED), an inorganic light emitting diode, or other type. Each pixel PXL can further include a plurality of TFTs and a storage capacitor in order to compensate for change in threshold voltage of the drive TFT.

The timing controller 110 rearranges digital video data RGB input from the outside so as to match the resolution of the display panel 100 and supplies the same (video data RGB) to the data drive circuit 120. In addition, the timing controller 110 generates a data control signal DDC for controlling the operation timing of the data drive circuit 120 and a gate control signal GDC for controlling the operation timing of the gate drive circuit 130 based on timing signals such as a vertical synchronization signal Vsync, a horizontal synchronization signal Hsync, a dot clock signal DCLK, and a data enable signal DE.

The data drive circuit 120 converts the digital video data RGB input from the timing controller 110 into an analog data voltage based on the data control signal DDC, and provides the same to each data line 140.

The data drive circuit 120 can include at least one source drive integrated circuit (IC) SIC. Under the control of the timing controller T-CON, the source drive IC SIC converts the digital video data of the input video to an analog gamma compensation voltage to generate a data voltage, and outputs the generated data voltage to the data lines 140. The source drive IC SIC can be mounted on a bendable flexible circuit board, such as a chip on film COF, or can be directly bonded to a substrate in a non-display area of the display panel 100 through a chip on glass (COG) process.

The COFs are bonded to a pad area of the display panel 100 and a source printed circuit board (PCB) via an anisotropic conductive film ACF. Input pins of the COFs are electrically connected to output terminals (pads) of the source PCB. Output pins of the source COFs are electrically connected to the data pads formed on the substrate of the display panel 100 via the ACF.

The gate drive circuit 130 can generate a scan signal and an emission signal based on the gate control signal GDC. The gate drive circuit 130 can include a scan driver and an emission driver. The scan driver and the emission driver can be configured with circuits. The scan driver can generate a scan signal in a row-sequential manner and can supply the scan signal to the gate lines 150 in order to drive at least one scan line connected to each pixel row of the display panel 100. The emission driver can generate an emission signal in a row-sequential manner and can supply the emission signal to the emission lines in order to drive at least one emission line connected to each pixel row of the display panel 100.

For example, the gate drive circuit 130 can be formed in the non-display area of the display panel 100 in a gate-driver in panel (GIP) fashion. As a variation, the gate drive circuit 130 can be formed in a display area of the display panel 100, or the gate drive circuit 130 can be formed outside the display panel 100. Embodiments of the present disclosure are not limited thereto.

The display apparatus including the display panel 100, the timing controller and the data driver circuit 120 can include other components and layers to operate the display apparatus, some of which may be know in the art.

Recently, various types of display panels that reflect the internal structure of the interior design of a vehicle have been needed. Among such display panels, a display panel having a certain curvature (e.g., extreme curvature or minimum curvature) such as a J-curved display panel or a C-curved display panel, a foldable display panel, and a rollable display panel can be considered to satisfy such needs since they not only satisfy consumers with design but also utilize the space of the display apparatus and can lead as the next-generation display apparatuses for the future. Here, J-curved displays can be used to provide complex 3-dimensional designs for gaming and vending machines, but can be used in other ways.

For heat dissipation of display panels, it may be necessary to attach a conductive plate to a rear surface of such display panel. For instance, when a conductive plate is to be attached to the rear surface of a J-curved display panel having an extreme curvature (minimum curvature), however, this attachment may not be possible or may be challenging due to the stiffness of the material of the conductive plate.

Further, when a thin sheet or thin film type conductive thin film having a low stiffness is to be attached to the rear surface of a J-curved display panel with an extreme curvature (minimum curvature), such attachment can be made. However, the thin film of the conductive thin film may be damaged by being crushed or stretched during the handling of the conductive thin film due to the low stiffness of the conductive thin film.

In addition, due to the configuration and material of the conductive thin film, when such a display apparatus is fastened to a set bracket after the attachment of the conductive thin film, the rear surface of the display panel may not be supported properly and the appearance of the display apparatus fastened to the set bracket may deteriorate.

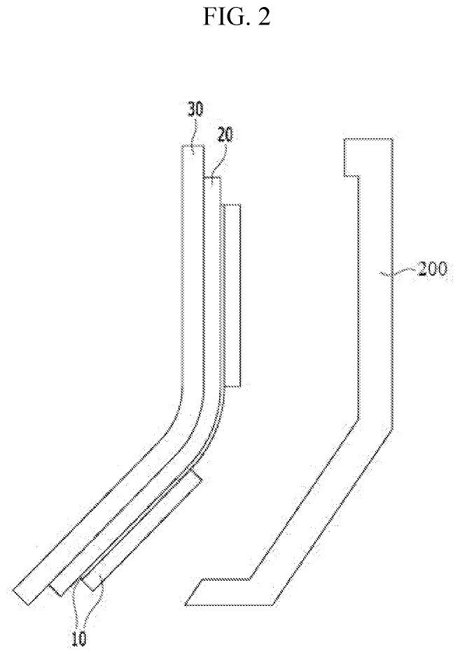

Therefore, a display apparatus capable of performing heat dissipation of the display panel and supporting the rear surface of the display panel when it is fastened is needed. And the display apparatus according to the various embodiments of the present disclosure provides such needs, and addresses these limitations and issues associated with a related art. FIGS. 2-4 provide examples of such display apparatus according to aspects of the present disclosure, which will now be described in more detail.

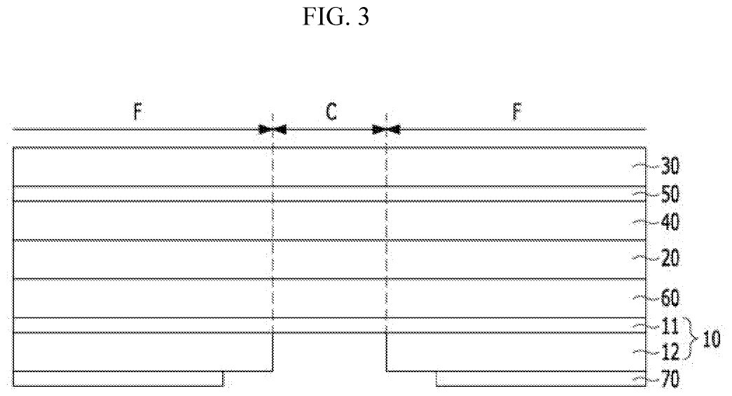

Particularly, FIG. 2 is a sectional view of a display apparatus according to an embodiment of the present disclosure, and FIG. 3 is a more detailed sectional view of the display apparatus of FIG. 2.

As shown in FIG. 2, the display apparatus according to the embodiment of the present disclosure can include a flexible plate 10, a display panel 20, and a cover member 30. The display panel 20 can be the same as or similar to the display panel 100, but can be other types of display panel.

Each of the flexible plate 10, the display panel 20, and the cover member 30 can include a curved portion having a certain curvature or minimum curvature such as an extreme curvature. Here, as an example, an extreme curvature can be an extremely deep curvature (e.g., in gaming monitors), a minimum curvature, a set curvature, etc. For instance, the display panel 20 can be a J-curved display panel, but can also be a different type of curved panel such as a C-curved display panel.

The cover member 30 is located on a display surface of the display panel 20, and the flexible plate 10 can be adhered to the rear surface of the display panel 20 via an adhesive member.

The display apparatus according to an example of the present disclosure, configured as described above, can be fastened to a set bracket 200. As an example, the set bracket 200 can be a bracket or other mounting structure (set bracket structure) for supporting the display panel 200, and can correspond to the curved configuration of the display panel 20. Other types of the set bracket 200 or the like can also be used.

As shown in FIG. 3, the display apparatus according to an example of the present disclosure can further include an optical film 40 disposed between the display panel 20 and the cover member 30. The optical film 40 can include a diffusion sheet, a prismatic sheet, and a polarizer, but other variations are possible.

The optical film 40 and the cover member 30 can be adhered to each other via an optically clear adhesive (OCA) 50.

The cover member 30 can include a cover glass and a cover window. A black layer can be further included in a bezel area of the cover member 30.

A support member 60 can be further included at the rear surface of the display panel 20.

The display panel 20 can include a light-emitting display panel. The display panel 20 can include a flexible substrate and a display element formed on the flexible substrate. The flexible substrate can include a polyimide substrate. The display panel 20 can be divided into one or more flat surfaces F and one or more curved portion C adjacent to and extending from one or more flat surfaces. In this example, the display panel 20 includes two flat surfaces F and one curved portion C disposed between the two flat surfaces F. The length of each of the flat surfaces F and curved portion C can vary. For instance, the top flat surface F can be the same as, longer or shorter than the bottom flat surface F, and the length of the curved portion C can be shorter than one or more of the flat surfaces F.

The flexible plate 10 can have functions to dissipate heat of the display panel 20 and to support the rear surface of the display panel 20. In an example, the flexible plate 10 includes a flexible thin sheet 11 made of a material having a good heat dissipation effect (e.g., material capable of dissipating heat well), such as graphite, copper (Cu), or aluminum (Al), and a plate 12 made of a material having high rigidity and a good heat dissipation effect, such as copper (Cu) or aluminum (Al).

The flexible thin sheet 11 can have a thickness of, for example, 100 um or less, for the attachment of a curvature region. The plate 12 can have a thickness of, for example, 200 um or more, for providing rigidity.

The plate 12 can be adhered to the flexible thin sheet 11 via a conductive adhesive. The plate 12 can be disposed at a position corresponding to the flat surface F or a gentle curvature portion of the display panel 20, excluding the curved portion C of the display panel 20.

The flexible plate 10 can be adhered to the rear surface of the display panel 20 or the support member 60 via a conductive adhesive.

When the flexible plate 10 is adhered to the rear surface of the display panel 20, the plate 12 can be adhered to the position corresponding to the flat surfaces F and the gentle curvature portion of the display panel 20, excluding the curved portion C. The flexible thin sheet 11 can be adhered to the rear surface of the display panel 20, including the curved portion C and the flat surface F.

The plate 12 of the flexible plate 10 and the set bracket 200 can be bonded to each other via a double-sided bonding member 70 or other bonding mechanism.

Consequently, the set bracket 200 may not contact directly the curved portion C but can be in contact or connected with the flat surface(s) F. For instance, the set bracket 200 can contact the double-sided bonding member 70 disposed only in the flat surface F areas (and not in the curved portion C area).

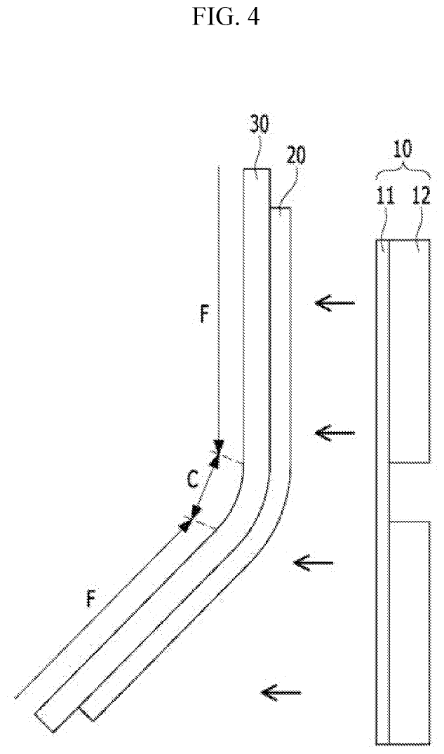

FIG. 4 is view illustrating a method of manufacturing a display apparatus according to an embodiment of the present disclosure. Particularly, FIG. 4 shows the flexible plate 10, the display panel 20, and the cover member 30 shown in FIG. 2 for easy description and identification; however, all the specific configuration and elements of the display apparatus shown in FIG. 3 can be fully included and applied in FIG. 4.

Referring to FIG. 4, the flexible plate 10 having the plate 12 adhered to the flexible thin sheet 11 is separately prepared.

Subsequently, the flexible plate 10 is adhered to a rear surface of the display panel 20 having the curved portion via an adhesive such as a conductive adhesive or the like.

At this time, the plate 12 of the flexible plate 10 is adhered to a position corresponding to the flat surface F and the gentle curvature portion of the display panel 20, excluding the curved portion C.

As described above, the flexible plate 10 having the plate 12 adhered to the flexible thin sheet 11 is separately prepared, and the flexible plate 10 is adhered to the rear surface of the display panel 20 via an adhesive such as a conductive adhesive. If the support member 60 is disposed on the rear surface of the display panel 20, then the the flexible plate 10 is adhered to the rear surface of the support member 60 attached to the rear surface of the display panel 20 via an adhesive such as a conductive adhesive.

Consequently, heat dissipation of the display panel 20 can be performed (e.g., heat of the display panel 20 can dissipate to the flexible plate 10), and at the same time, the rear surface of the display panel 20 can be supported well when the display apparatus is fastened to the set bracket 200.

In the display apparatus according to an embodiment of the present disclosure, a plurality of flat surfaces F can be provided, and correspondingly a plurality of plates 10 can be included. The plates 10 can be spaced apart from each other in the state in which the curved portion is interposed therebetween.

According to one or more aspects of the present disclosure, by providing the flexible plate 10 that can be curved correspondingly to the curvature of the display panel 20, heat dissipation can be provided, which can further enhance the attachment of the set bracket 200 to the display panel 20 having the flexible plate 10 attached thereto.

A display apparatus according to an aspect of the present disclosure can include a flexible display panel having a curved portion, a cover member attached to a display surface of the display panel, and a flexible plate adhered to a rear surface of the display panel, wherein the flexible plate can include a flexible thin sheet and at least one plate.

In some embodiments of the present disclosure, the flexible plate can include a flexible thin sheet including a material having a heat dissipating effect and at least one plate including a material having a heat dissipating effect.

According to an aspect of the present disclosure, the at least one plate can be disposed at a position corresponding to a flat surface or a gentle curvature portion of the display panel, excluding the curved portion.

According to an aspect of the present disclosure, a set bracket can be further disposed at a rear surface of the flexible plate, and the set bracket may not overlap the curved portion but can overlap the flat surface.

According to an aspect of the present disclosure, the flexible thin sheet can be adhered to the rear surface of the display panel, including the curved portion.

According to an aspect of the present disclosure, the at least one plate can include at least one of copper and aluminum. The at least one plate can have a thickness of 200 um or more.

According to an aspect of the present disclosure, the flexible thin sheet can include at least one of graphite, copper, and aluminum. The flexible thin sheet can have a thickness of 100 um or less. The at least one plate can be provided in plural in a state of being spaced apart from each other.

According to an aspect of the present disclosure, an optical film can be further provided between the display panel and the cover member, wherein the optical film and the cover member can be adhered to each other via an optically clear adhesive.

According to an aspect of the present disclosure, the at least one plate can include a plurality of plates separated and spaced apart from each other, and the plurality of plates are disposed on the flexible thin film sheet.

According to an aspect of the present disclosure, the flexible display panel can further include a plurality of flat surfaces with the curved portion disposed between the plurality of flat surfaces, and the plurality of plates are adhered correspondingly to the plurality of flat surfaces of the display panel.

According to an aspect of the present disclosure, a support member can be further provided between the display panel and the flexible plate. The flexible display panel can be a J-curved display panel.

As is apparent from the above description, a display apparatus according to an embodiment of the present disclosure and a method of manufacturing the same have advantageous features including, but not limited to, the following effects.

According to an aspect of the present disclosure, a flexible plate having a plate adhered to a flexible thin sheet is separately prepared, and the flexible plate is adhered to a rear surface of a display panel via an adhesive. Consequently, it is possible to perform heat dissipation of the display panel and to support the rear surface of the display panel when the display apparatus is fastened to a set bracket.

According to an aspect of the present disclosure, since the flexible plate can be easily adhered to the rear surface of the display panel, the process can be optimized, and therefore energy or power used in the production of the display apparatus can be reduced.

The display apparatus according to various embodiments of the present disclosure can be applied to various electronic apparatuses. For example, the display apparatus according to the embodiments of the present disclosure can be applied to mobile devices, video phones, smart watches, watch phones, wearable devices, foldable devices, rollable devices, bendable devices, flexible devices, curved devices, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, TVs, wall paper display apparatuses, signage apparatuses, game machines, notebook computers, monitors, cameras, camcorders, and home appliances, or the like.

The description of problems and limitations to be solved or addressed, means to solve or address the problems and limitations, and effects of the present disclosure do not specify essential features of the claims, and the scope of the claims is not limited by the description of the invention.

Those skilled in the art will understand that various modification and alternations are possible from the above description without departing from the technical idea of the present disclosure. Consequently, the technical scope of the present disclosure is defined by the appended claims, not by the detailed description of the present disclosure.

What is claimed is:

1. A display apparatus comprising:
a flexible display panel having a curved portion;
a cover member attached to a display surface of the flexible display panel; and
a flexible plate adhered to a rear surface of the flexible display panel,
wherein the flexible plate comprises a flexible thin sheet and at least one plate.

2. The display apparatus according to claim 1, wherein the flexible thin sheet comprises a material configured to dissipate heat; and
wherein the at least one plate comprises a material configured to dissipate heat.

3. The display apparatus according to claim 2, wherein the at least one plate is disposed at a position corresponding to a flat surface or a gentle curvature portion of the flexible display panel, excluding the curved portion of the flexible display panel.

4. The display apparatus according to claim 3, further comprising;
a set bracket structure disposed at a rear surface of the flexible plate,
wherein the set bracket structure contacts the at least one plate corresponding to the flat surface or gentle curvature portion of the flexible display panel, excluding the curved portion of the flexible display panel.

5. The display apparatus according to claim 2, wherein the flexible thin sheet is adhered to the rear surface of the flexible display panel including a rear surface of the curved portion.

6. The display apparatus according to claim 2, wherein the material configured to dissipate heat in the at least one plate comprises at least one of copper and aluminum.

7. The display apparatus according to claim 2, wherein the at least one plate has a thickness of about 200 um or more.

8. The display apparatus according to claim 2, wherein the material configured to dissipate heat in the flexible thin sheet comprises at least one of graphite, copper, and aluminum.

9. The display apparatus according to claim 2, wherein the flexible thin sheet has a thickness of about 100 um or less.

10. The display apparatus according to claim 2, wherein the at least one plate includes a plurality of plates separated and spaced apart from each other, and
wherein the plurality of plates are disposed on the flexible thin sheet.

11. The display apparatus according to claim 10, wherein the flexible display panel further includes a plurality of flat surfaces with the curved portion disposed between the plurality of flat surfaces, and
wherein the plurality of plates are adhered correspondingly to the plurality of flat surfaces of the display panel.

12. The display apparatus according to claim 1, further comprising:
an optical film provided between the flexible display panel and the cover member,
wherein the optical film and the cover member are adhered to each other via an optically clear adhesive.

13. The display apparatus according to claim 1, further comprising a support member provided between the flexible display panel and the flexible plate.

14. The display apparatus according to claim 1, wherein the flexible display panel is a J-curved display panel.

15. A method of manufacturing a display apparatus, the method comprising:
preparing a flexible plate having at least one plate adhered to a flexible thin sheet; and
adhering the flexible plate composed of the at least one plate and the flexible thin sheet to a rear surface of a flexible display panel having a curved portion,
wherein the flexible plate is configured to dissipate heat from the flexible display panel.

16. The method according to claim 15, wherein the flexible thin sheet comprises a material configured to dissipate heat, and
wherein the at least one plate comprises a material configured to dissipate heat.

17. The method according to claim 16, wherein the at least one plate is disposed at a position corresponding to a flat surface or a gentle curvature portion of the flexible display panel, excluding the curved portion of the flexible display panel.

18. The method according to claim 17, further comprising:
adhering a set bracket structure to a rear surface of the flexible plate,
wherein the set bracket structure contacts the at least one plate corresponding to the flat surface or gentle curvature portion of the flexible display panel, excluding the curved portion of the flexible display panel.

19. The method according to claim 15, wherein the display apparatus further includes a cover member attached to a display surface of the flexible display panel, and an optical film provided between the flexible display panel and the cover member, and
wherein the optical film and the cover member are adhered to each other via an optically clear adhesive.

20. The method according to claim 15, wherein the at least one plate has a thickness of about 200 um or more, or
wherein the flexible thin sheet has a thickness of about 100 um or less.
